(19) United States
(12) Patent Application Publication
(10) Pub. No.: US 2005/0023440 A1
(43) Pub. Date: Feb. 3, 2005

(54) Integrated optical detector and diffractive optical element

(76) Inventor: James Albert Matthews, Milpitas, CA (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/632,167

(22) Filed: Jul. 30, 2003

(51) Int. Cl. H01L 31/00; H01J 40/14

(52) U.S. Cl. 250/214.1; 250/214 R

(57) ABSTRACT

An integrated optical detector and diffractive optical element includes a sensing element and a diffractive optical element. The sensing element and diffractive optical element are placed directly into the path of the beam emitted by the light source. The sensing element monitors the power of a light source, without diverting or reflecting light away from its beam. The diffractive optical element consists of a plurality of thin layers of optically transmissive material stacked on top of one another. An additional layer at the base of the diffractive optical element acts as a sensing element that is responsive to the power of an incident light beam. The response of the sensing element to light includes photoresistive, photovoltaic, and thermal responses. The sensing element may also be incorporated as part of the optical element. The optical element used with the sensing element may also be refractive or reflective.

### FIELD OF THE INVENTION

The invention is directed towards semiconductor laser optical devices and more specifically, towards optical detectors for monitoring light from a semiconductor laser light source.

### BACKGROUND OF THE INVENTION

Fiber optic laser transmitters generally require a power monitor to control the laser. For example, a Vertical Cavity Surface Emitting Laser (VCSEL), which is often used in fiber optic laser transmitters, needs a power monitor to keep its output steady over time and temperature changes. Most VCSELs have only one output facet, and monitoring the light output is typically done by deflecting a portion of the VCSEL's forward beam. An optical element is inserted into the forward beam to deflect a portion of the beam towards an optical detector, where the beam power is monitored. However, this arrangement is often difficult to implement, as the space available in modern optical module designs is very limited. This is especially true in parallel optic modules, in which multiple transmitters are aligned in a row to transmit an array of beams.

### SUMMARY OF THE INVENTION

In a preferred embodiment of the present invention, an integrated optical detector and diffractive optical element (hereinafter referred to as an integrated detector,) is positioned directly in the path of the light beam emitted by the light source, so that it can monitor the light without deflecting light away from the light beam. The integrated detector includes both a diffractive optical element and a sensing element. The diffractive optical element may be a diffractive lens, or other optical device. The sensing element is an additional layer of optically transmissive material at the base of the diffractive optical element that is responsive to the power of a light beam. A control circuit measures the response of the sensing element and adjusts the light source accordingly.

In a preferred embodiment, the sensing element is a layer of photoresistive amorphous silicon, such that the resistance of the sensing element is proportional to the power of the light passing through. The power of the light beam is monitored by determining the resistance of the sensing element.

In an alternate embodiment, the sensing element is a photovoltaic PN junction formed by two adjacent layers. The light hitting the PN junction induces a current and a voltage across the PN junction via the photovoltaic effect. The induced current and voltage are proportional to the power of the light beam. By determining the current or voltage across the sensing element, the power of the light beam can be monitored.

In an alternate embodiment, the sensing element is incorporated into the diffractive optical element. The sensing element can be anywhere within the diffractive optical element, as long as the appropriate contacts are made to the sensing element for measuring its response.

Further features and advantages of the present invention, as well as the structure and operation of preferred embodiments of the present invention, are described in detail below with reference to the accompanying exemplary drawings. In the drawings, like reference numbers indicate identical or functionally similar elements.

### BRIEF DESCRIPTION OF THE DRAWINGS

FIG. 1 shows a high-level diagram of a fiber optic transmitter that uses an integrated detector, made according to the present invention.

FIG. 2A shows a top view of an integrated detector made according to the present invention.

FIG. 2B shows a cross-sectional view of the same integrated detector shown in FIG. 2A.

FIG. 3A shows a top view of an alternate embodiment of an integrated detector.

FIG. 3B shows a cross-sectional view of the same integrated detector shown in FIG. 3A.

### DETAILED DESCRIPTION

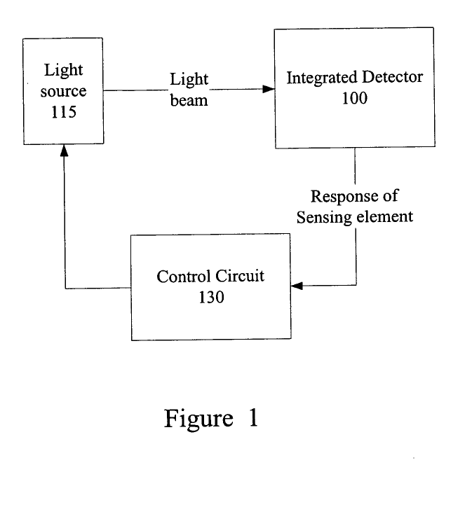

FIG. 1 shows a high-level diagram of a fiber optic transmitter that uses an integrated detector 100, made according to the present invention. The integrated detector 100 diffracts, detects, and monitors light from a light source 115. The integrated detector 100 includes a diffractive optical element and a sensing element that is responsive to incident light. A control circuit 130 measures the response of the sensing element and adjusts the light source 115 accordingly, if needed. The integrated detector 100 and the control circuit 130 essentially form a feedback loop for controlling the light output from the light source 115.

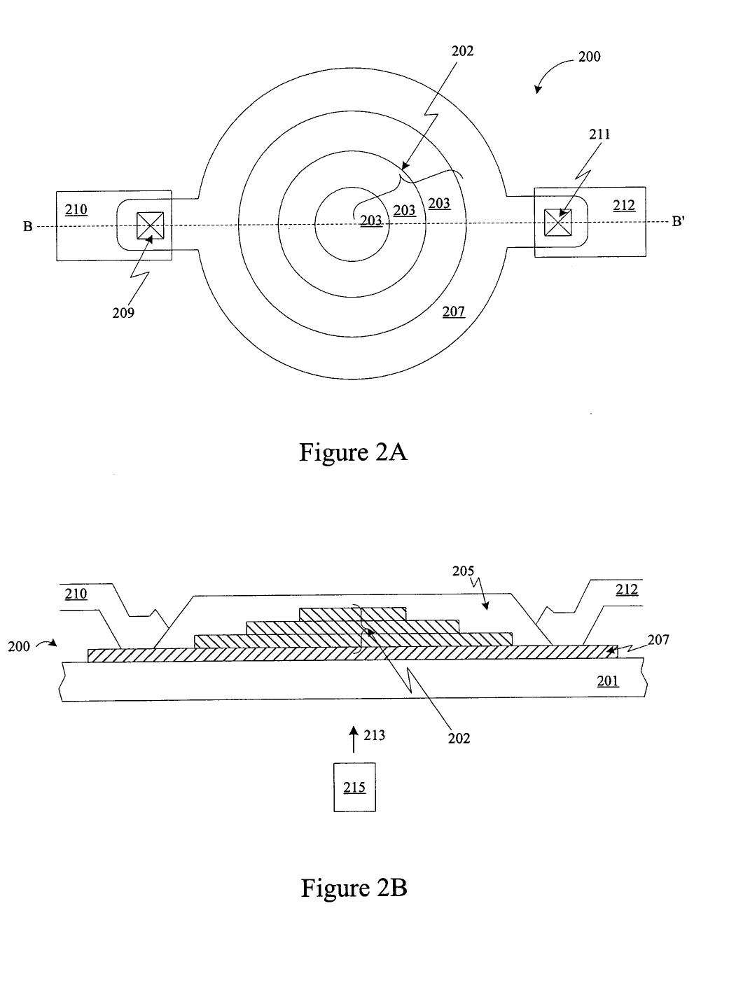

FIGS. 2A and 2B show a preferred embodiment of an integrated detector 200 made in accordance with the teachings of the present invention. FIG. 2A shows a top view of the integrated detector 200. FIG. 2B shows a cross-sectional view of the same integrated detector 200 in FIG. 2A, taken along the line B-B′. The integrated detector 200 is formed on a substrate 201. The substrate 201 is typically made of quartz, although glass, silicon, gallium arsenide, and other optically transmissive materials are also suitable.

The integrated detector 200 includes a diffractive optical element 202 and a sensing element 207 that is responsive to incident light. An optional protective oxide layer 205 covers the diffractive optical element 202 and sensing element 207. A first contact 209 connects the sensing element 207 to a first interconnect 210. A second contact 211 connects the sensing element 207 to a second interconnect 212.

Light 213 is transmitted from a light source 215 (such as a VCSEL, light-emitting diode, or other light-emitting device) and passes through both the sensing element 207 and the diffractive optical element 202. Since the sensing element 207 is naturally positioned in the pathway of the transmitted light beam 213, there is no need to deflect the light beam 213 in order to monitor its power.

The diffractive optical element 202 is formed using well-known conventional semiconductor fabrication techniques. Very thin layers 203 of silicon are deposited on top of one another. The layers 203 are separated by thin insulating layers of silicon dioxide (not shown). The diffractive optical element 202 may also be made with any other optically transmissive material. Using well-known photolithography methods, the layers 203 are then etched into the desired shape, such as a diffractive lens, filter, or hologram. Only a few disk-shaped layers are shown in the figures for the sake of clarity, but it should be understood that many more layers and many different shapes may be used in actual practice. Examples of diffractive optical elements 202 may be found in co-pending U.S. application Ser. No. 10/208570, entitled “Diffractive Optical Elements And Methods Of Making The Same”, filed Jul. 30, 2002, by James Albert Matthews et al, which is herein incorporated by reference.

In this exemplary embodiment, the sensing element 207 is an additional photoresistive layer between the diffractive optical element 202 and substrate 201, deposited and etched using well-known semiconductor fabrication techniques. It is insulated from the diffractive optical element 202 with another layer of silicon dioxide (not shown).

When the sensing element 307 is exposed to light 213, some of the light is absorbed. The energy of the absorbed light knocks electrons within the sensing element 207 from the valence band into the conduction band. The resistance of the sensing element 207 is lowered due to the increased number of free carriers. In fact, the resistance is proportional to the amount of light absorbed: the more light that is absorbed by the sensing element 207, the more carriers are knocked free and the lower its resistance will be. Therefore, the power of the light 213 emitted by the light source 215 can be monitored by simply measuring the resistance of the sensing element 207 between the two contacts 209 and 211. To obtain an accurate reading of the resistance of the sensing material, the second contact should be located as far as possible from the first contact 207.

The sensing element 207 has a thickness that is sufficient to sense the light 213 emitted by the light source 215 without unduly attenuating it. The amount of attenuation that can be tolerated will vary from application to application, and therefore so will the thickness of the sensing element 207. The sensing element 207 can be made from any material that is both photoresistive and optically transmissive to the light emitted by light source 215. The material must also be smooth enough for optics, because rough material will scatter light and cause losses. In the preferred embodiment, the sensing element is made with Plasma Enhanced Chemical Vapor Deposition (PECVD) amorphous silicon and used with a light source transmitting light with a wavelength less than 1000 nm. Low Pressure Chemical Vapor Deposition (LPCVD) may also be used to form the sensing element 207 if it is run at low enough temperatures to ensure smooth surfaces in the deposited material.

The material used in the sensing element 207 must be matched to the wavelength of the light 213. It must be able to sense the light without unduly attenuating it. Furthermore, the bandgap of the material must be small enough so that energy absorbed from the incident light is sufficient to excite electrons from the valence band into the conduction band. If the bandgap of the material is too large, then the incident light will not have enough energy to knock electrons into the conduction band and change the resistance of the material. For example, for short wavelength (approximately 850 nm) lasers, PECVD amorphous silicon is an ideal material for the sensing element 207 since it transmits most of the light at 850 nm, but also absorbs enough of the light to change its resistance as well. In fact, amorphous silicon is a suitable material for all light having wavelengths less than approximately 1000 nm. However, PECVD amorphous silicon is completely transparent at longer wavelengths (approximately greater than 1000 nm) of light. At these wavelengths, PECVD amorphous silicon no longer absorbs enough light to affect its resistance, and therefore is no longer suitable for use as the sensing element 207. A more suitable material would be germanium, which has a lower bandgap than silicon.

Other materials that may be suitable for use in the sensing element 207 include: any semiconductor (such as silicon, carbon, germanium, and the like) and their alloys; any compound semiconductor (such as GaAs, InP, InGaAs, InGaAsP, InSb, and the like) and their alloys; semiconductor compounds and alloys with other elements (such as hydrogenated amorphous silicon); and organic semiconductors. The sensing element 207 and the diffractive optical element 202 may be made with the same material, but this is not a necessity.

In an alternate embodiment, the sensing element 207 is incorporated into the diffractive optical element 202 as one of its layers 203. The sensing element 207 can be any layer within the diffractive optical element 202, as long as the appropriate contacts are made to that layer for measuring its resistance. The thickness of the sensing element 207, its shape, and other design constraints must be considered, since the sensing element 207 must conform to the design requirements of the diffractive optical element 202 for proper diffraction of the light beam 213.

Furthermore, more than one layer 203 in the diffractive optical element can be used to detect and monitor the light as well. Multiple adjacent layers can serve as sensing elements 207 by simply omitting any insulating material between them so that the layers are electrically coupled to one another. Multiple non-adjacent layers can also serve as sensing elements by making the appropriate contacts to the desired layers.

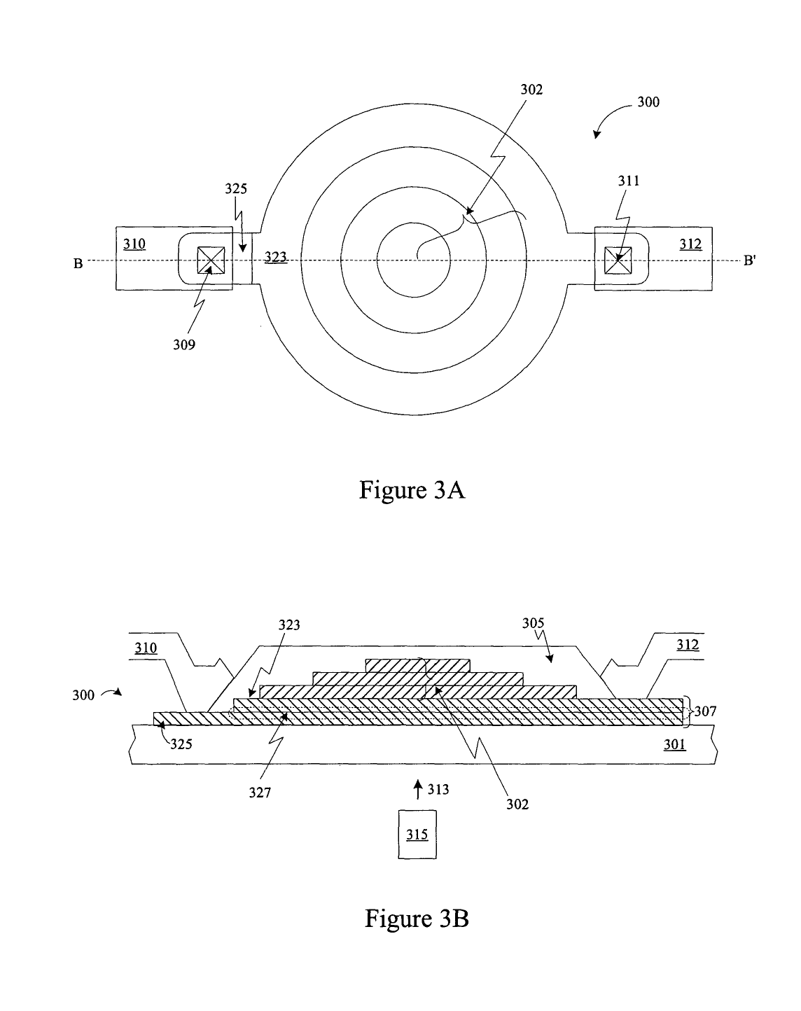

FIGS. 3A and 3B show an alternate embodiment made in accordance with the teachings of the present invention. FIG. 3A shows a top view of an integrated detector 300. FIG. 3B shows a cross-sectional view of the same integrated detector 300 in FIG. 3A, taken along the line B-B′. The integrated detector 300 includes a diffractive optical element 302 and a sensing element 307 that is responsive to incident light.

In this embodiment, the sensing element 307 is a photovoltaic cell. The sensing element 307 is formed from the juxtaposition of two different layers of plasma CVD amorphous silicon. One of the layers is a positively doped (P-type) layer 323. An adjacent layer is a negatively doped (N-type) layer 325. The two layers form a PN junction 327 that is essentially a photovoltaic cell. A first contact 309 connects the P-type layer 323 to a first interconnect 310. A second contact 311 connects the N-type layer 325 to a second interconnect 312. When light 313 strikes the PN junction 327, the energy from the light excites carriers within the PN junction 327 and knocks them into the conduction band.

The free carriers are swept up by the electric field created by the PN junction 327, forming a current that is proportional to the power of the incident light 313. By measuring the current generated by the light 313, its power can be monitored. Alternatively, the voltage drop across the PN junction 327 or the power consumed by the PN junction 327 can be measured to monitor the power of the light 313.

The PN junction in sensing element 307 can be made from any material that is both photovoltaic and optically transmissive to the wavelength of light emitted by light source 315. Suitable materials include: any semiconductor (such as silicon, carbon, germanium, and the like) and their alloys; any compound semiconductor (such as GaAs, InP, InGaAs, InGaAsP, InSb, and the like) and their alloys; semiconductor compounds and alloys with other elements (such as hydrogenated amorphous silicon); and organic semiconductors. The sensing element 307 and the diffractive optical element 302 may be made with the same material, but this is not required.

In an alternate embodiment, the PN junction of sensing element 307 is incorporated into the diffractive optical element 302 as two of its layers. Any two adjacent layers within the diffractive optical element 302 can be used as the sensing element 307, as long as the layers are doped accordingly to form a PN junction, and the appropriate contacts are made to those layers for measuring the current or voltage across the PNjunction. The thickness of the sensing element 307 and other design constraints must be considered, since the sensing element 307 must conform to the design requirements of the diffractive optical element 302 for proper diffraction of the light beam 313. The substrate may also serve as one or both of the layers in the PN junction.

Other embodiments are within the scope of the claims. For example, other kinds of diffractive optical elements that are well known in the art may also be used with the sensing element in the various embodiments described above. For further details regarding diffractive optical elements, see “Micro-Optics Elements, Systems and Applications”, edited by Hans Peter Herzig, published by Taylor and Francis Ltd. in 1997, ISBN 0-7484-0481-3. Optical devices other than diffractive optical elements may also be used in conjunction with a sensing element. For example, refractive or reflective optical devices may also be used with a sensing element.

The sensing element may have other properties that are responsive to light. For example, the temperature of the sensing element may be measured to determine the power of light. Furthermore, the sensing element may also be deposited over the various optical devices.

Although the present invention has been described in detail with reference to particular preferred embodiments, persons possessing ordinary skill in the art to which this invention pertains will appreciate that various modifications and enhancements may be made without departing from the spirit and scope of the claims that follow.

1. An apparatus, comprising:
a substrate;
a sensing element that is responsive to incident light, including at least one layer of optically transmissive material formed over the substrate; and
an optical device formed over the substrate.

2. The apparatus as in claim 1, wherein the optical device is a diffractive optical element

3. The apparatus as in claim 2, wherein the diffractive optical element is a plurality of stacked layers of optically transmissive material upon the substrate,

4. The apparatus as in claim 3, further comprising:
a light source positioned to transmit light through the sensing element and the diffractive optical element.

5. The apparatus as in claim 4, further comprising:
a control circuit coupled to the sensing element for measuring the response of the sensing element to incident light, and for controlling the light source.

6. The apparatus as in claim 5, wherein the light source is a laser.

7. The apparatus as in claim 3, wherein the resistance of the sensing element is responsive to incident light.

8. The apparatus as in claim 7, wherein the sensing element is at least one of the layers in the diffractive optical element.

9. The apparatus as in claim 7, wherein the sensing element is adjacent to the diffractive optical element.

10. The apparatus as in claim 7, further comprising:
a first and second contact on the sensing element for measuring the resistance of the sensing element.

11. The apparatus as in claim 10, wherein the optically transmissive material includes a semiconductor.

12. The apparatus as in claim 3, wherein the sensing element includes two layers of optically transmissive material that form a photovoltaic PN junction.

13. The apparatus as in claim 12, wherein the substrate is one of the layers that form a photovoltaic PN junction.

14. The apparatus as in claim 12, further comprising:
a first contact on a first layer of the PN junction; and
a second contact on a second layer of the PN junction,
wherein the first and second contacts are used to measure an electrical characteristic of the PN junction.

15. The apparatus as in claim 12, wherein the sensing element is at least one of the layers in the diffractive optical element.

16. The apparatus as in claim 12, wherein the sensing element is adjacent to the diffractive optical element.

17. The apparatus as in claim 1, wherein the optical device is refractive.

18. The apparatus as in claim 1, wherein the optical device is reflective.

19. The apparatus as in claim 1, wherein the temperature of the sensing element is responsive to light.
